(19) United States
(12) Patent Application Publication
(10) Pub. No.: US 2025/0054818 A1
(43) Pub. Date: Feb. 13, 2025

(54) SEMICONDUCTOR WAFER CONFIGURED FOR SINGLE TOUCH-DOWN TESTING

(71) Applicant: Sandisk Technologies, Inc., Milpitas, CA (US)

(72) Inventors: Akira Ogawa, Tokyo (JP); Takashi Murai, Yokohama (JP)

(73) Assignee: Sandisk Technologies, Inc., Milpitas, CA (US)

(21) Appl. No.: 18/930,628

(22) Filed: Oct. 29, 2024

Related U.S. Application Data
(63) Continuation-in-part of application No. 18/221,797, filed on Jul. 13, 2023.
(60) Provisional application No. 63/415,924, filed on Oct. 13, 2022.

(51) Int. Cl. H01L 21/66; H01L 23/00; H01L 25/065; H01L 25/18; H10B 80/00

(52) U.S. Cl. CPC H01L 22/34; H01L 22/32; H01L 24/06; H01L 25/18; H01L 24/48; H01L 25/0657; H01L 2224/06132; H01L 2224/48145; H01L 2225/06506; H01L 2225/06562; H01L 2924/1438; H10B 80/00

(57) ABSTRACT

An apparatus includes a semiconductor wafer including a first die and a second die, each including, a selector circuit including a first input terminal coupled to a first die bond pad, a second input terminal, and an output terminal, the selector circuit configured to selectively couple the first input terminal and the second input terminal to the output terminal, a conductor selectively configured to couple the second input terminal to either a first power supply or a second power supply, and an address determined based on a signal value at the output terminal of the selector circuit.

### PRIORITY CLAIM

This application is a continuation-in-part of U.S. patent application Ser. No. 18/221,797, filed Jul. 13, 2023, which claims priority from U.S. Provisional Patent Application No. 63/415,924, filed Oct. 13, 2022, each of which is incorporated by reference herein in its entirety for all purposes.

### BACKGROUND

The strong growth in demand for portable consumer electronics is driving the need for high-capacity storage devices. Non-volatile semiconductor memory devices, such as flash memory storage cards, are widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, cellular telephones and SSDs (Solid State Drives).

Semiconductor memory may be provided within a semiconductor package, which protects the semiconductor memory and enables communication between the memory and a host device. Examples of semiconductor packages include system-in-a-package (SiP) or multichip modules (MCM), where a plurality of die are mounted and interconnected on a small footprint substrate. Semiconductor die are typically batch processed together in a semiconductor wafer. Once the integrated circuits have been defined on the individual die, the die are diced from the wafer and removed for mounting within a package.

To identify faulty semiconductor die before they are mounted within a semiconductor package, it is known to test semiconductor die after formation while still part of the wafer. Conventional semiconductor test equipment has test heads matching a configuration of the die on the wafer. The test heads are attached to a probe card having pins which provide electrical signals to each die on wafer. The probe cards measure output signals of each die and the test equipment compares output signals against expected values for the purpose of testing if each die operates as specified in its design specifications.

A current problem with semiconductor test equipment is that the number of die on a wafer has increased to the point where they outnumber the test heads on the test equipment. The result is that conventional test operations require two touch-downs to test all die on a wafer. A first set of die is tested in a first touch-down, the wafer or test equipment is shifted and then the second set of die is tested in a second touch-down. Requiring two touch-downs doubles the time it takes to perform semiconductor test operations and adds cost and inefficiencies to the test process.

### BRIEF DESCRIPTION OF THE DRAWINGS

Like-numbered elements refer to common components in the different figures.

FIG. 1 is a flowchart for forming a wafer with semiconductor die and laser grooves according to embodiments of the present technology.

FIG. 2 is a front view of a semiconductor wafer showing a first major surface of the wafer.

FIG. 3 is a front view of a portion of a semiconductor wafer including semiconductor die and traces in the scribe lines according to embodiments of the present technology.

FIG. 4 is a front view of a portion of a semiconductor wafer including semiconductor die and traces in the scribe lines at an edge of the wafer according to embodiments of the present technology.

FIG. 5 is a schematic perspective view of a semiconductor test assembly according to embodiments of the present technology.

FIG. 6 is a top view of a portion of a semiconductor die including an address pad coupled to a pull-down resistor according to embodiments of the present technology.

FIG. 7 is a top view of a portion of a semiconductor wafer juxtaposed next to a bottom view of a portion of a probe card according to embodiments of the present technology.

FIG. 8 is a top view of a portion of a semiconductor wafer with a portion of a probe card (shown in phantom) seated thereon according to embodiments of the present technology.

FIGS. 9A and 9B are top views of a first semiconductor die coupled to a pull-down resistor and a second semiconductor die coupled to a pull-up resistor, respectively, according to embodiments of the present technology.

FIG. 10 is a front view of a portion of a semiconductor wafer including the first and second semiconductor die of FIGS. 9A and 9B and traces in the scribe lines according to embodiments of the present technology.

FIG. 11 is a top view of a portion of a semiconductor wafer juxtaposed next to a bottom view of a portion of a probe card according to embodiments of the present technology.

FIG. 12 is a top view of a portion of a semiconductor wafer with a portion of a probe card (shown in phantom) seated thereon according to embodiments of the present technology.

FIG. 13 is a top view of a semiconductor die coupled to a pull-down resistor according to embodiments of the present technology.

FIG. 14 is a front view of a portion of a semiconductor wafer including the semiconductor die of FIG. 13 and traces in the scribe lines according to embodiments of the present technology.

FIG. 15 is a top view of a portion of a semiconductor wafer juxtaposed next to a bottom view of a portion of a probe card according to embodiments of the present technology.

FIG. 16 is a top view of a portion of a semiconductor wafer with a portion of a probe card (shown in phantom) seated thereon according to embodiments of the present technology.

FIG. 17 illustrates a perspective view of a semiconductor die fabricated according to embodiments of the present technology.

FIG. 18 is a perspective view of a semiconductor device including semiconductor die fabricated according to embodiments of the present technology including addressing bond wires.

FIG. 19 is a front view of a semiconductor device including semiconductor die and addressing bond wires fabricated according to embodiments of the present technology.

FIG. 20 is a front view of a semiconductor device including semiconductor die and addressing bond wires fabricated according to further embodiments of the present technology.

FIG. 21 is a front view of a semiconductor device including semiconductor die and addressing bond wires fabricated according to still further embodiments of the present technology.

FIG. 22 is an edge view of a finished semiconductor device according to embodiments of the present technology.

FIGS. 23A and 23B are top views of a pair of die from a wafer according to another embodiment of this technology.

FIG. 24 depicts an embodiment of the pair od die of FIGS. 23A-23B coupled to a test head for die sort testing.

FIG. 25 is a diagram depicting multiple die pairs each coupled to a corresponding test head for die sort testing.

FIG. 26 depicts an embodiment in which eight die are coupled to a test head for die sort testing.

FIG. 27 is a flow diagram of a process for performing a single touch-down die sort testing of multiple semiconductor die on a wafer.

### DETAILED DESCRIPTION

Technology is described to perform die sort testing of multiple die on a wafer in a single touch down of a probe card. In embodiments, each die on a wafer has a chip address that may be selectively switched between a corresponding die sort chip address and an address that may be specified using one or more chip address bond pads.

In embodiments, the die sort chip address of each die may be configured during manufacture using a metal or via option. For example, different layout data may be used to configure different die sort chip addresses to the die on a wafer, such as by taping out multiple kinds of layout data that have a variety of different die sort chip addresses.

In embodiments during die sort testing, the chip address of multiple die on a wafer are selectively switched to their corresponding die sort chip address. In embodiments, a die sort test is performed in a single touch down of a probe card on the die on a wafer. In embodiments, the probe card includes test pins configured to touch down and couple together corresponding channels of the test pads to a single test head.

In an embodiment, the present technology relates to a semiconductor wafer including pairs of die having test pads which are electrically coupled to each other to enable testing of pairs of die at the same time. In this way, even wafers having large numbers of die can be tested with a semiconductor test assembly in a single touch-down test process.

In an embodiment, the semiconductor test assembly includes a set of test heads, electrically coupled to a probe card. In an embodiment, the probe card includes pins that couple to the test pads on one of the die in a pair of coupled die.

In an embodiment, to distinguish between two common channels of a pair of coupled die, one die may have traces which electrically couple a chip address pad to a first power supply (e.g., GROUND) on the probe card while the other die has traces which electrically couple the chip address pad to a second power supply (e.g., VDD) on the probe card. Thus, in an embodiment pairs of die may be tested simultaneously, while distinguishing test signals on a shared channel from the die pairs.

In a further embodiment, the present technology relates to a semiconductor device including a stack of die mounted to a substrate. Like channels on the different semiconductor die are electrically coupled to each other and the substrate using bond wires. Additionally, the different die in the stack may be uniquely addressed using the addressing pads on each die in the stack, and a unique configuration of addressing bond wires to the addressing pads on each die in the stack.

Persons of ordinary skill in the art will understand that the disclosed technology may be embodied in many different forms and should not be construed as being limited to the embodiments set forth herein. Rather, these embodiments are provided so that this disclosure will be thorough and complete and will fully convey the technology to those skilled in the art.

Indeed, the disclosed technology is intended to cover alternatives, modifications and equivalents of these embodiments. Furthermore, in the following detailed description of the present technology, numerous specific details are set forth to provide a thorough understanding of the technology. However, it will be clear to those of ordinary skill in the art that the disclosed technology may be practiced without such specific details.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation.

Also, as used herein, the terms “substantially” and/or “about” mean that a specified dimension or parameter may be varied within an acceptable manufacturing tolerance for a given application.

For purposes of this disclosure, a connection may be a direct connection or an indirect connection (e.g., via one or more other parts). In some cases, when a first element is referred to as being connected, affixed, mounted or coupled to a second element, the first and second elements may be directly connected, affixed, mounted or coupled to each other or indirectly connected, affixed, mounted or coupled to each other.

When a first element is referred to as being directly connected, affixed, mounted or coupled to a second element, then there are no intervening elements between the first and second elements (other than possibly an adhesive or melted metal used to connect, affix, mount or couple the first and second elements).

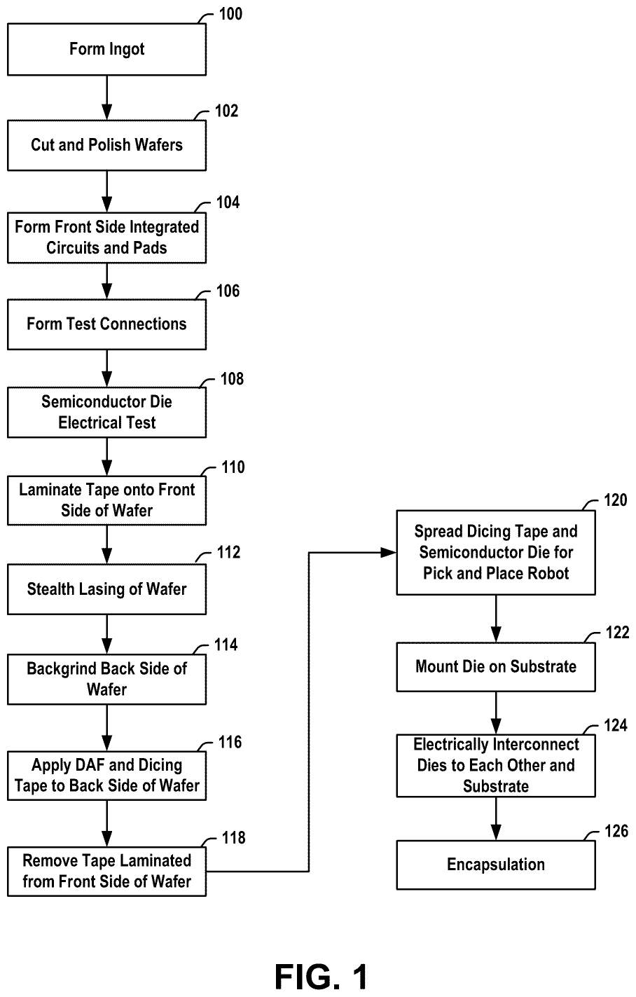

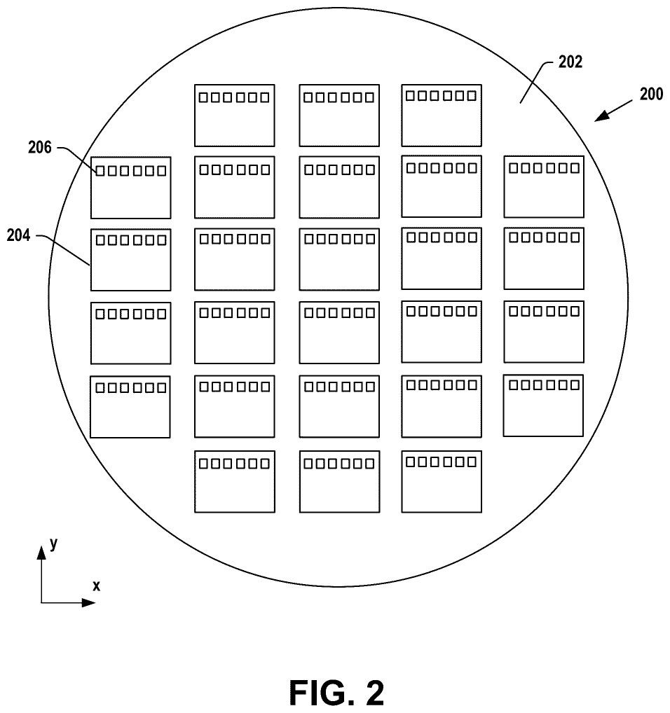

An embodiment of the present technology will now be explained with reference to the flowchart of FIG. 1, and the views of FIGS. 2-22. Referring initially to the flowchart of FIG. 1, a semiconductor wafer 200 (FIG. 2) may start as an ingot of wafer material which may be formed in step 100. For simplicity, semiconductor wafer 200 will be referred to in the remaining description as wafer 200. In one example, the ingot from which wafers 200 are formed may be monocrystalline silicon grown according to either a Czochralski (CZ) or floating zone (FZ) process. However, wafer 200 may be formed of other materials and by other processes in further embodiments.

In step 102, wafer 200 may be cut from an ingot and polished on both a first major surface 202 (FIG. 2), and a second major surface opposite first major surface 202, to provide smooth parallel surfaces. In step 104, first major surface 202 may undergo various processing steps to divide wafer 200 into respective die 204 (one of which is numbered in FIG. 2), and to form integrated circuits in active areas of the respective die 204 on and/or in first major surface 202.

These various processing steps may include photolithographic steps and metallization steps depositing metal traces and contacts for transferring signals to and from the integrated circuits. The electrical contacts may include die bond pads 206 (one of which is numbered in FIG. 2) exposed on first major surface 202. Die bond pads 206 may be formed along one of the long edges of die 204.

Die 204 on semiconductor wafer 200 may be oriented horizontally to each other (e.g., along an x-axis), and oriented vertically to each other (e.g., along a y-axis). The number of die 204 shown on wafer 200 in FIG. 2 is for illustrative purposes, and wafer 200 may include more or fewer die 204 than are shown. In embodiments, the integrated circuits may be configured as flash memory such as 2D NAND flash memory or 3D BiCS (Bit Cost Scalable), V-NAND or other 3D flash memory, though other types of integrated circuits are contemplated.

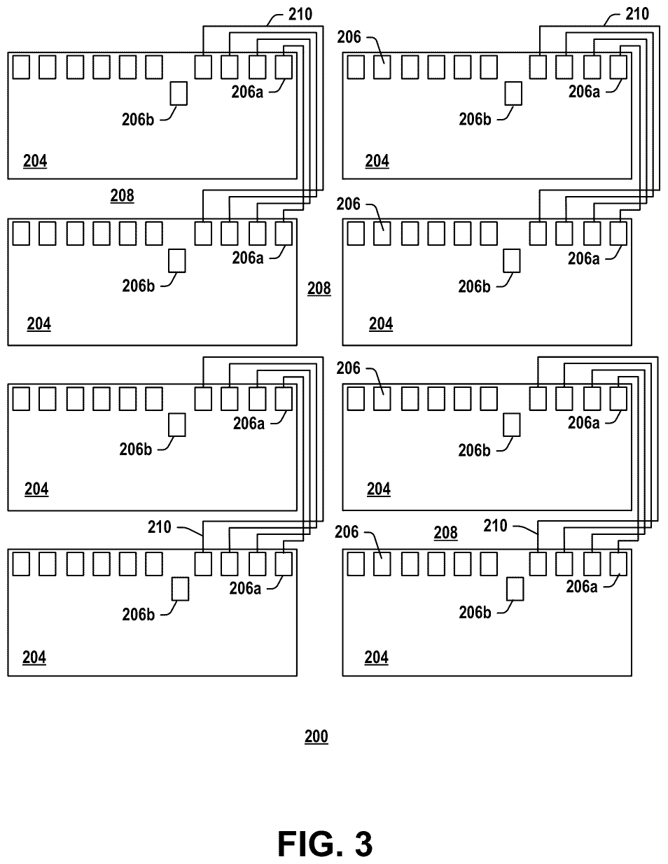

FIG. 3 is an enlarged top view showing a number of die 204 from a portion of wafer 200. Each of die 204 may be separated from each other by scribe lines 208 which extend vertically and horizontally around each die 204. Scribe lines 208 do not include integrated circuits for the operation of die 204 and do not form part of the active areas of die 204. Scribe lines 208 are at least partially removed when die 204 are diced from wafer 200 as explained below.

As shown, each die 204 may include die bond pads 206 to transfer signals to/from the die. Die bond pads 206 on each die 204 include a set of bond pads 206a which are used as test pads for testing the operation of each die 204. Although four test pads 206a are shown, there may be more or less in further embodiments.

Die bond pads 206 may further include a bonding-option pad 206b which gets coupled to a first power supply (e.g., GROUND) or a second power supply (e.g., VDD) of a semiconductor die test assembly as explained below. Bonding-option pad 206b is shown out of line with the other die bond pads 206 for clarity, but may be aligned with the other die bond pads 206.

The number of die bond pads 206 shown on each die 204 on semiconductor wafer 200 in FIGS. 2 and 3 is for illustrative purposes, and each die 204 may include more die bond pads 206 than are shown. Die bond pads 206 may for example be formed of aluminum, or alloys thereof, but die bond pads 206 may be formed of other materials in further embodiments.

In an embodiment, in step 106 test pads 206a of pairs of die 204 are electrically coupled to each other with electrical traces 210, extending between the die pairs in scribe lines 208. Die 204 electrically coupled by electrical traces 210 are at times referred to herein as die pairs. All die 204 may be similarly configured on wafer 200.

In the example illustrated in FIG. 3, test pads 206a of vertically adjacent die 204 are coupled together. However, in further embodiments, some of which are explained below, test pads 206a of horizontally adjacent die 204 may be coupled together. Electrical traces 210 are formed such that corresponding channels on each die 204 in a die pair are coupled together.

Electrical traces 210 may be formed in step 106 after the formation of the integrated circuits in step 104 using a reticle in which electrical traces 210 are formed on top of first major surface 202 in scribe lines 208 by photolithography. In further embodiments, electrical traces 210 may be formed within first major surface 202 during the metallization processes of step 104.

In particular, during the formation of integrated circuits in each die 204 in step 104, a number of metal layers are formed within first major surface 202 including a pattern of electrical traces for transferring signals to and from the integrated circuits of each die 204.

In embodiments, the metal layers are separated from each other by silicon dioxide or other dielectric material, and the traces of the different metal layers are coupled to each other and bond pads 206 by plated or filled vias extending orthogonally between the metal layers. In an embodiments electrical traces 210 may be formed in one of these metal layers in step 104 to couple test pads 206a of a pair of die 204.

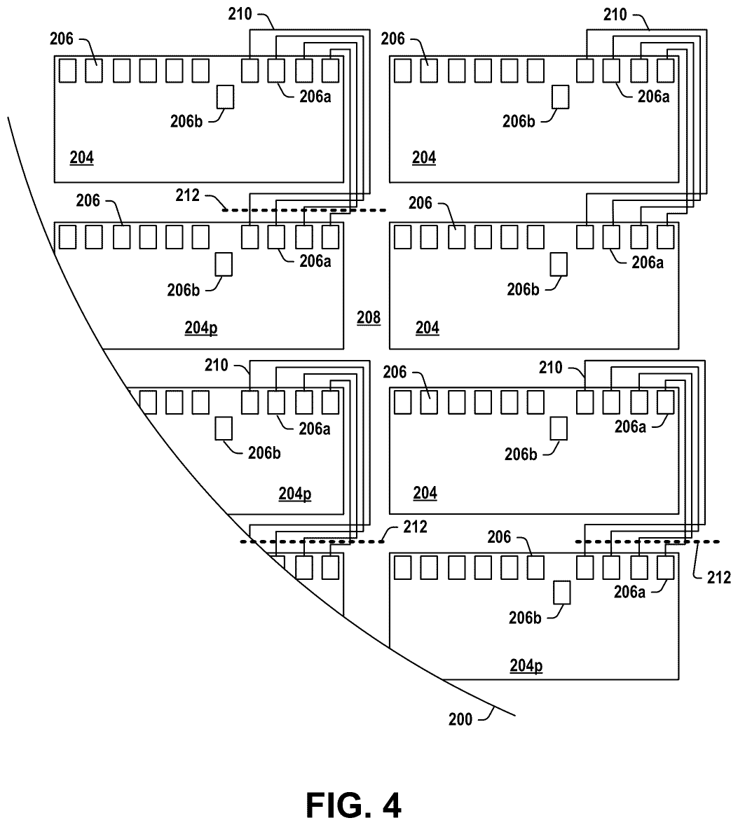

FIG. 4 illustrates a top view of an edge of wafer 200. As shown, some die 204 may be partially formed at an edge of wafer 200. For these partial die 204p, electrical traces 210 may be severed, for example by a laser forming cut lines 212, so that partial die 204p do not get tested by the semiconductor test assembly (explained below). In further embodiments, these partial die 204p may be mapped and identified before electrical traces 210 are formed. In such an embodiment, electrical traces 210 may be omitted from any partial die 204p.

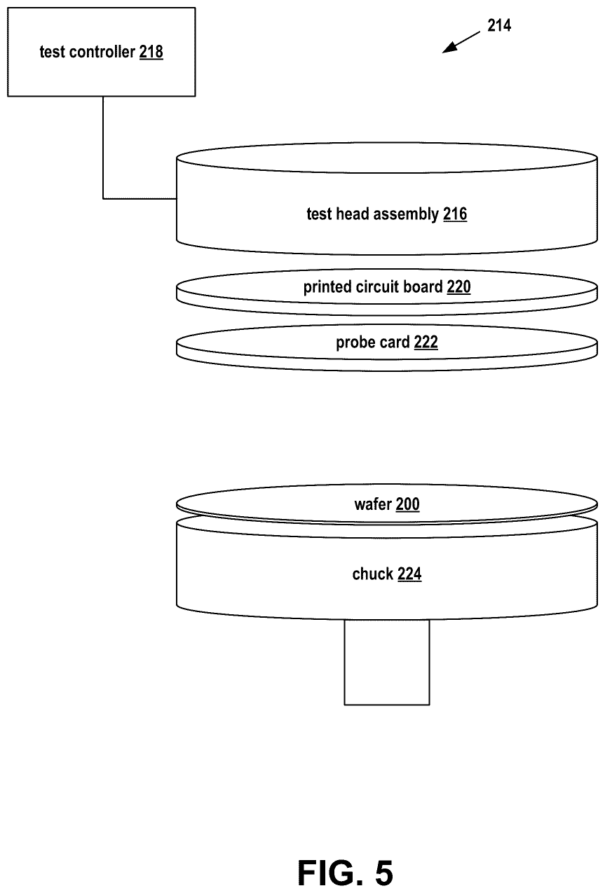

In step 108, die 204 on wafer 200 may be operationally tested, or sorted, by a semiconductor test assembly 214 (also referred to herein as test assembly 214), schematically shown in FIG. 5. In an embodiment, test assembly 214 includes a test head assembly 216 that includes a pattern of test heads (not shown). Each test head includes test circuits connected to a test controller 218 which supplies power and logic signals to the test circuits of the test heads.

Conventionally, test head assembly 216 would include a pattern of test heads that match the pattern of die 204 on wafer 200 to enable parallel (simultaneous) testing of all die 204 on wafer 200. However, at times this is no longer possible, for example where the number of die 204 is larger than the number of test heads. This mismatch is a problem addressed by the present technology.

Test assembly 214 further includes a printed circuit board (PCB) 220 affixed to test head assembly 216, and a probe card 222 affixed to PCB 220. Although test head assembly 216, PCB 220 and probe card 222 are shown spaced from each other for clarity in FIG. 5, those components may be affixed to each other in implementation.

In an embodiment, probe card 222 includes individual die contact circuits 222a (not shown), each including a pattern of pins configured to touch-down on test pads 206a and voltage pads on die 204 on wafer 200. In embodiments, die contact circuits 222a are configured on probe card 222 for a specific configuration of die 204 on wafer 200. In an embodiment, probe card 222 includes one die contact circuit 222a for each pair of die 204 on wafer 200. In another embodiment, probe card 222 includes one die contact circuit 222a for each die 204 on wafer 200.

In an embodiment, each die contact circuit 222a includes a pattern of pins configured to touch-down on test pads 206a and voltage pads on a pair of die 204 on wafer 200 connected by electrical traces 210. During the test operation step 108, wafer 200 may be supported on a chuck 224. In an embodiment, with wafer 200 supported on chuck 224, the pins of die contact circuits 222a of probe card 222 touch-down on test pads 206a, bonding-option pads 206b and (in embodiments) other pads on wafer 200 as explained below to enable parallel testing of all die 204 on wafer 200 at the same time.

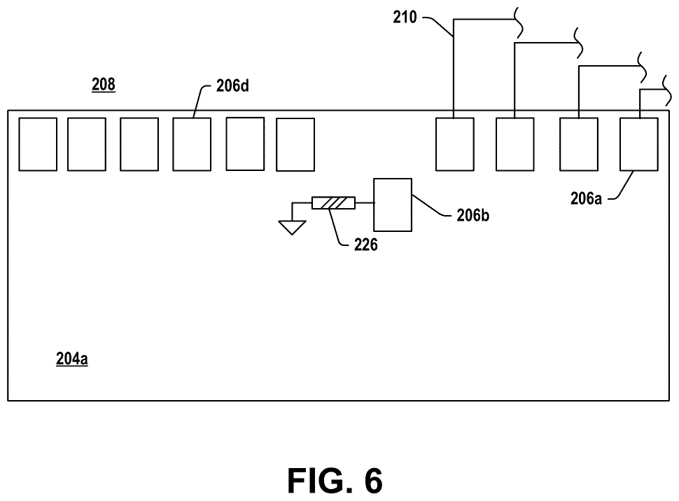

FIG. 6 illustrates an embodiment of a die 204a from wafer 200 having die bond pads 206 including test pads 206a as described above. Electrical traces 210 are partially shown in scribe lines 208 for coupling test pads 206a of die 204a to test pads 206a of a second die 204a (not shown) as described above.

In this example, bonding-option pad 206b is coupled to a pull-down resistor 226, which is coupled within die 204a to a first power supply (e.g., GROUND) on die 204a. Bonding-option pad 206b may for example be chip address pads CADD #0, CADD #1 and CADD #2 typically provided in NAND flash memory die.

In an embodiment, pull down resistor 226 functions as a weak on-chip pull down to GROUND, meaning that in the absence of a connection of bonding-option pad 206b to a power source, bonding-option pad 206b is set to a logical 0. However, if bonding-option pad 206b is connected to a second power supply (e.g., VDD) by a bonding wire, bonding-option pad 206b will have a logical 1.

In an embodiment, pull-down resistor 226 forms a leakage path from the power source to GROUND, but the leakage can be suppressed with the high resistance of pull down resistor 226. In an embodiment, this configuration is used to assign a logical address 0 to a first die 204a and logical address 1 to a second die 204a in a pair of die coupled by electrical traces 210.

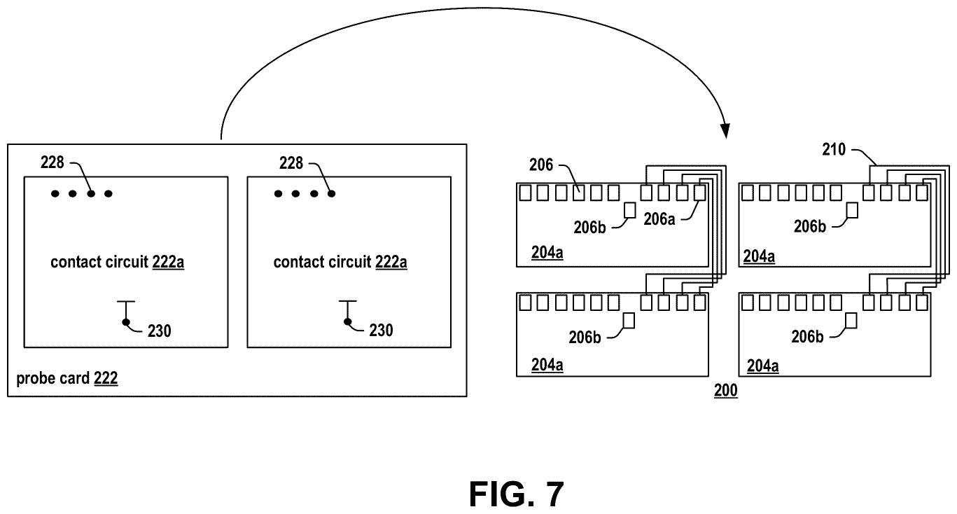

FIG. 7 illustrates an embodiment of a portion of wafer 200 (to the right) including four die 204a. In an embodiment, the portion of wafer 200 shown includes a first pair of die 204a electrically coupled together with electrical traces 210 in scribe lines 208, and a second pair of die 204a electrically coupled together with electrical traces 210 in scribe lines 208. FIG. 7 also shows an embodiment of bonding-option pads 206b on each die 204a. In an embodiment, bonding-option pads 206b on each die 204a have pull-down resistors 226 as described above. To avoid obscuring the drawing, pull-down resistors 226 are not shown in FIG. 7.

FIG. 7 further illustrates two die contact circuits 222a of an embodiment of probe card 222 (to the left), each die contact circuit 222a including test pins 228 and power pin 230. Persons of ordinary skill in the art will understand that probe card 222 typically includes more than two die contact circuits 222a. In an embodiment, all die contact circuits 222a are identical, and each are customized for wafer 200 to touch-down on a corresponding pair of die 204a connected by electrical traces 210.

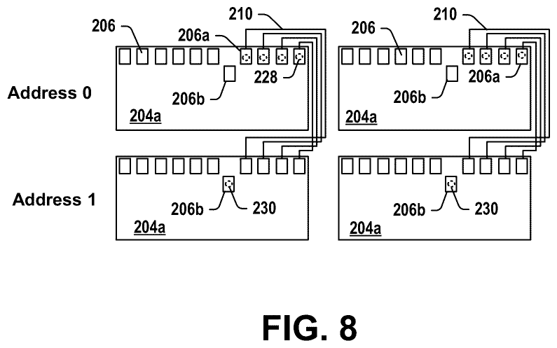

FIG. 7 shows an embodiment of a top view of the portion of wafer 200 and bottom view of the portion of probe card 222 and die contact circuits 222a. As indicated by the arrow, in an embodiment probe card 222 (and die contact circuits 222a) would be flipped over when supported on PCB 220 so that when probe card 222 touches down on wafer 200 as shown in FIG. 8, test pins 228 of die contact circuits 222a touch-down on test pads 206a on one of the die 204a in each die pair.

In the embodiment shown, test pins 228 are positioned on each die contact circuit 222a to touch-down on the top die 204a of each die pair. In another embodiment, test pins 228 alternatively may be positioned lower down on each die contact circuit 222a to touch-down on the bottom die 204a of each die pair.

In an embodiment, each die contact circuit 222a is coupled to a corresponding test head of test head assembly 216. In an embodiment, with each die pair electrically coupled by electrical traces 210, signals are transmitted to and from the test heads of test head assembly 216 through PCB 220 and test pins 228 on each die contact circuit 222a to test each die pair simultaneously.

In an embodiment, from the perspective of the test heads of test head assembly 216, each die pair is treated as a single larger die, in effect halving the number of die 204a to be tested by the test heads. Without wanting to be bound by any particular theory, it is believed that even if wafer 200 includes large numbers of die 204a, effectively halving the number of die 204a leaves more than enough test heads to simultaneously test each of the die pairs in a single touch-down.

In an embodiment, because electrical traces 210 couple like channels on each die pair, simply testing each die pair with test pins 228 would not enable the test heads of test head assembly 216 and test controller 218 to distinguish between like channels on die 204a in the die pair. Thus, if test controller 218 detects faulty signals on a channel of a die pair, test controller 218 needs the ability to distinguish which die 204a in a die pair resulted in that faulty signal. In an embodiment, this information is given by power pin 230 on each die contact circuit 222a. Power pin 230 may be connected through probe card 222 and PCB 220 to a power supply (e.g., VDD) in the test assembly.

In an embodiment, in the absence of a voltage, pull-down resistor 226 assigns the top die 204a of each die pair to logical Address 0. In the embodiment shown in FIG. 8, when die contact circuit 222a touches down on wafer 200, power pin 230 mates with bonding-option pad 206b on the bottom die 204a of each die pair, and overcomes the bias of the GROUND connection of bonding-option pad 206b to thus assign Address 1 to the bottom die 204a in each die pair.

This allows the channels on each die 204a in a die pair to be distinguished from each other, for example enabling the die 204a with Address 0 to be tested first, and enabling the die 204a with Address 1 to be tested second (or vice-versa). In an embodiment, using the unique addresses provided by the touch-down of the power pins 230 on bonding-option pads 206b of die 204a, the die 204a in each die pair may be tested simultaneously in further embodiments.

In an embodiment, the positions of power pins 230 on die contact circuit 222a may be switched to assign Address 1 to the top die 204a in each die pair, and Address 0 to the bottom die 204a of each die pair. Moreover, given the connections of electrical traces 210, the die 204a in each die pair are vertically oriented with respect to each other in FIGS. 7 and 8. However, as noted, in further embodiments, the die 204a in each die pair may be horizontally oriented with respect to each other.

In an embodiment, the positions of test pins 228 and power pin 230 on each die contact circuit 222a accordingly may be adjusted where die pairs are horizontally oriented to provide the appropriate contact of test pins 228 with test pads 206a on one of the die 204a of each die pair, and to provide the appropriate contact of power pins 230 with bonding-option pads 206b on each die 204a of each die pair.

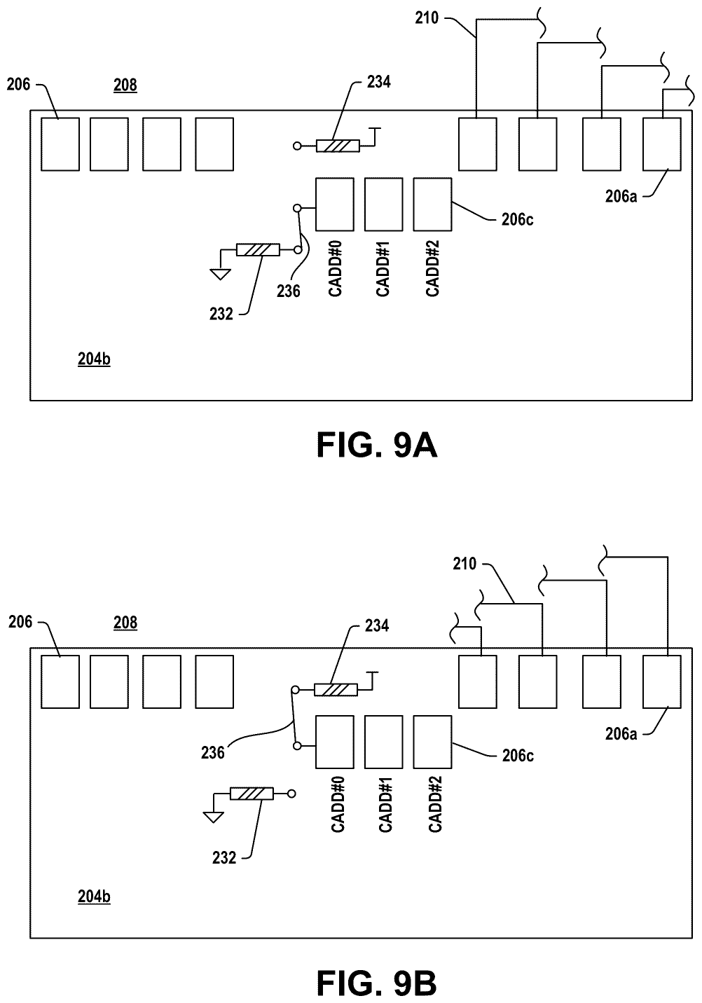

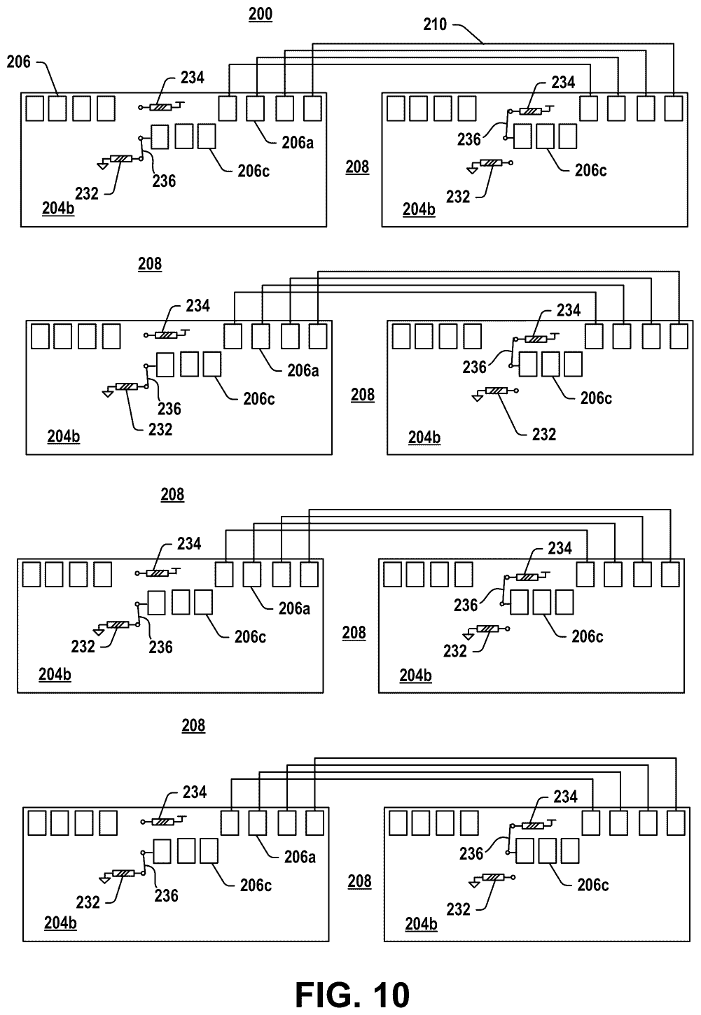

FIGS. 9A-12 illustrate an alternative embodiment of the present technology. In this embodiment, each die 204b includes die bond pads 206, including test pads 206a, as described above. In an embodiment, each pair of die 204b may be electrically coupled together with electrical traces 210 in scribe lines 208 as described above (in the example shown in FIG. 10, the die 204b in each die pair are horizontally oriented with respect to each other).

In this embodiment, instead of using bonding-option pads 206b, the die 204b in each die pair are distinguished from each other using die bond pads 206c which are chip address pads CADD #0, CADD #1 and CADD #2. This embodiment further includes a pull-down resistor 232 and a pull-up resistor 234 as explained below. This embodiment further includes trace 236 on each die 204b which (in this embodiment) is coupled at one end to CADD #0. As explained below, trace 236 may be coupled to CADD #0, CADD #1 and/or CADD #2 in further embodiments.

FIG. 9A shows a top view a first die 204b in a die pair, with a second end of trace 236 coupled to pull-down resistor 232. FIG. 9B shows a top view of a second die 204b in a die pair, with a second end of trace 236 coupled to pull-up resistor 234. Pull-up resistor 234 functions similarly to pull-down resistor 232, but is instead coupled to a voltage source for a weak pull up to logical 1.

In an embodiment, trace 236 performs as a switch, coupling one or more of the CADD pads 206c to either pull-down resistor 232 or pull-up resistor 234. In an embodiment, trace 236 also is referred to herein as a switching trace 236. Pull-down resistor 232 and pull-up resistor 234 may be formed in step 104 when die 204b are defined in wafer 200. Alternatively, pull-down resistor 232 and pull-up resistor 234 may be formed or affixed on top of first major surface 202 after die 204b are defined in wafer 200.

In an embodiment, traces 236 may be formed in the metallization layers within first major surface 202 during step 104, or traces 236 may be formed on top of first major surface 202 after die 204b are defined in wafer 200, using for example a reticle. In an embodiment, upon completion traces 236 may couple half the number of die 204b on wafer 200 to pull-down resistor 232, and the other half the number of die 204b on wafer 200 to pull-up resistor 234.

FIG. 10 is a top view of a portion of wafer 200 showing four die pairs. In an embodiment, each die 204b is horizontally coupled to its neighboring die 204b with electrical traces 210. In the example illustrated in FIG. 10, a first die 204b in each die pair (left column of die 204b) has the CADD pad(s) 206c coupled to pull-down resistor 232 via trace 236. A second die 204b in each die pair (right column of die 204b) has the CADD pad(s) 206c coupled to pull-up resistor 234 via trace 236. The remainder of die 204b may be similarly configured on wafer 200 in this embodiment. In further embodiments, the die 204b in each die pair may alternatively be vertically oriented with respect to each other, similar to the embodiment shown in FIG. 6.

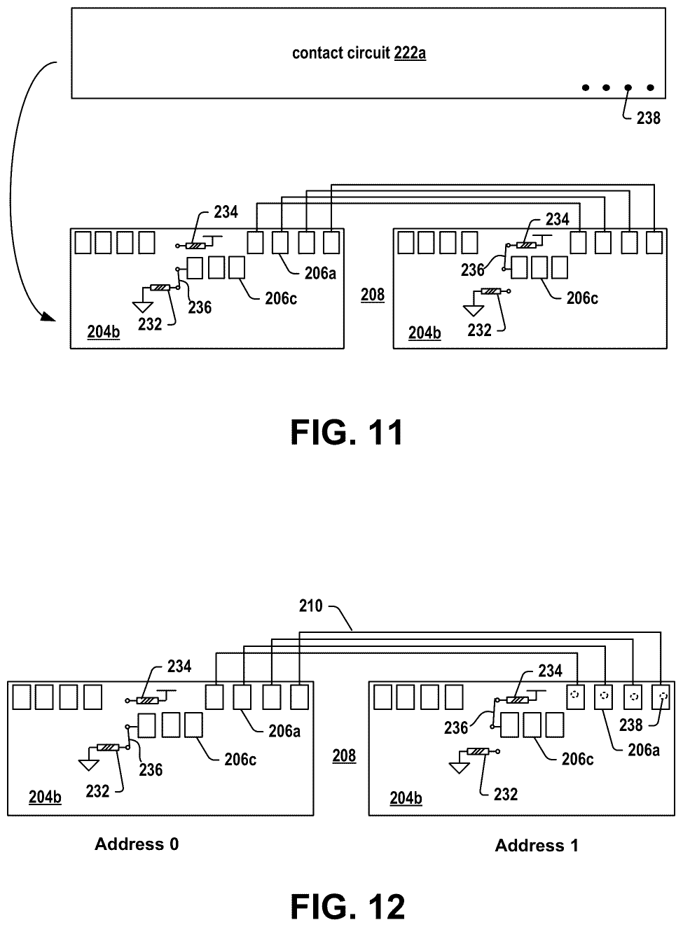

FIG. 11 illustrates a portion of wafer 200 (at the bottom) including two die 204b. As explained above, the depicted portion of wafer 200 includes a pair of die 204b electrically coupled together with electrical traces 210 in scribe lines 208, with a first die 204b connected to pull-down resistor 232 by trace 236 and a second die 204b connected to pull-up resistor 234 by trace 236.

FIG. 11 further illustrates an embodiment of die contact circuit 222a (at the top) of probe card 222 including test pins 238. To avoid obscuring the drawing, probe card 222 is not shown in FIG. 11. In an embodiment, all die contact circuits 222a are identical, and each are customized for wafer 200 to touch-down on each pair of die 204b connected by electrical traces 210.

FIG. 11 shows a top view of the portion of wafer 200 and bottom view of die contact circuit 222a. In an embodiment, as indicated by the arrow, probe card 222 (and die contact circuit 222a) would be flipped over when supported on PCB 220. In such an embodiment, when die contact circuit 222a touches down on wafer 200 as shown in FIG. 12, test pins 238 touch-down on test pads 206a on one of the die 204b in each die pair.

In the embodiment shown, test pins 238 are positioned on each die contact circuit 222a to touch-down on the right side die 204b of each die pair. In further embodiments, test pins 238 may be positioned at the opposed side on each die contact circuit 222a to touch-down on the left side die 204b of each die pair.

With each die pair electrically coupled to one another by electrical traces 210, signals are transmitted to and from test heads of test head assembly 216 through PCB 220 and each die contact circuit 222a to test each die pair simultaneously. Thus, as above, even where wafer 200 includes large numbers of die 204b, effectively halving the number of die leaves more than enough test heads of test head assembly 216 to simultaneously test each of the die pairs in a single touch-down. In accordance with the present technology, signals from like channels of a given die pair are distinguished from each other by pull-down resistor 232 and pull-up resistor 234.

As shown in FIG. 12, when die contact circuit 222a touches down on wafer 200, trace 236 in the left side die 204b is coupled to pull-down resistor 232, thus pulling the CADD #0 pad down to logical Address 0. Similarly, when die contact circuit 222a touches down on wafer 200, trace 236 in the right side die 204b is coupled to pull-up resistor 234, thus pulling the CADD #0 pad up to logical Address 1.

This allows the channels on each die 204b in a die pair to be distinguished from each other, for example enabling the die 204b with Address 0 to be tested first, and enabling the die 204 with Address 1 to be tested second (or vice-versa). As noted, the unique addresses of the first and second die 204b allow them to be tested simultaneously in further embodiments.

The connection of trace 236 to pull-down resistor 232 or pull-up resistor 234 in FIG. 12 may be switched to assign Address 1 to the left side die 204b in each die pair, and Address 0 to the right side die 204b of each die pair. Moreover, as noted, in further embodiments, the die 204b in each die pair may be vertically oriented with respect to each other.

The positions of test pins 238 on each die contact circuit 222a may be adjusted accordingly where die pairs are vertically oriented to provide the appropriate contact of test pins 238 with test pads 206a of each die pair. Although shown connected to pad CADD #0, the connection may be made to any of the CADD pads 206c.

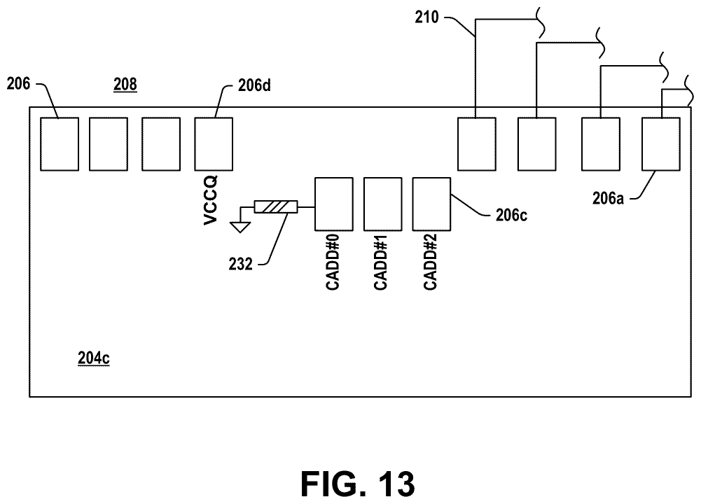

FIGS. 13-16 illustrate another alternative embodiment of the present technology. In this embodiment, each die 204c includes die bond pads 206, including test pads 206a, as described above. In an embodiment, each pair of die 204c may be electrically coupled together (in a vertical or horizontal orientation) with electrical traces 210 in scribe lines 208 as described above. This embodiment also uses chip address pads CADD #0, CADD #1 and/or CADD #2 (pads 206c) typically provided in NAND flash memory die to distinguish the die 204c in each die pair from each other.

In this embodiment, a pull-down resistor 232 is coupled to one of die bond pads 206c (CADD #0 in the illustrated embodiment) to provide a weak pull-down of the connected pad to logical 0. This embodiment further makes use of a VCCQ power pad 206d provided as one of die bond pads 206 on die 204c. The position of VCCQ power pad 206d is shown by example only and may be in other positions in implementation.

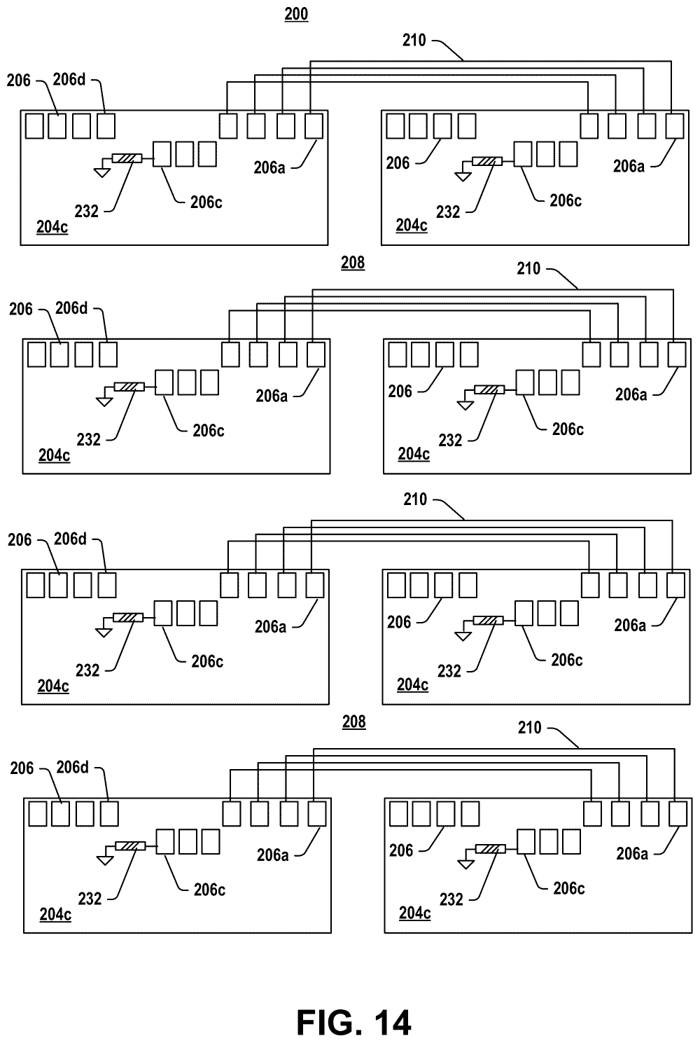

FIG. 14 is a top view of a portion of wafer 200 showing four die pairs, each pair horizontally coupled to its neighboring die 204c with electrical traces 210. In the example illustrated in FIG. 14, all die 204c are identical to each other, each including pull-down resistor 232 electrically coupled to one of CADD pads 206c. In this embodiment, the die 204c in each die pair may alternatively be vertically oriented with respect to each other, similar to the embodiment shown in FIG. 6.

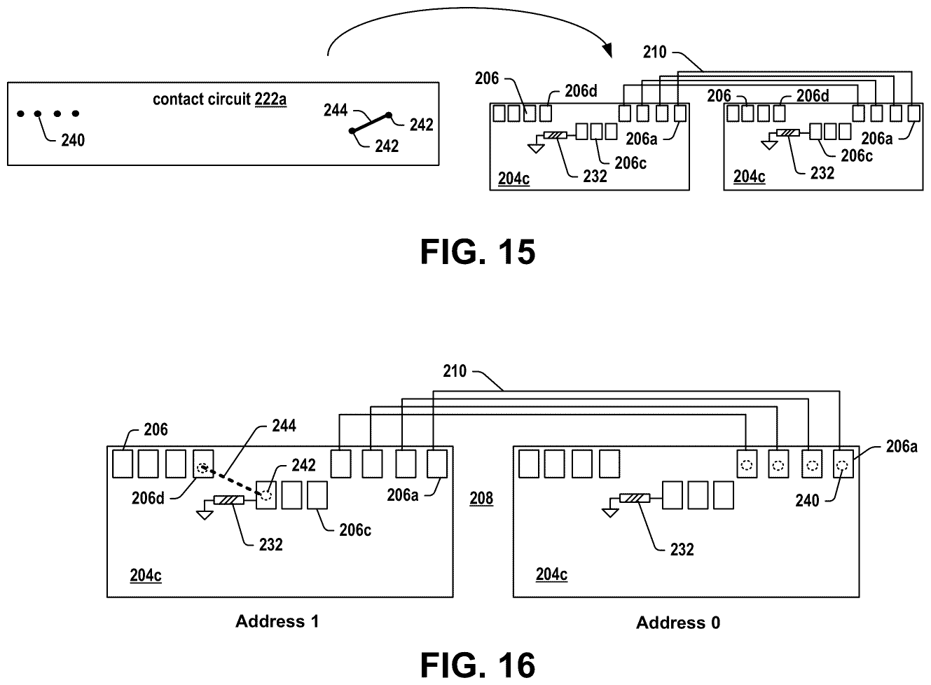

FIG. 15 illustrates a portion of wafer 200 (to the right) including two die 204c. As explained above, the portion of wafer 200 shown includes a pair of die 204c electrically coupled together with electrical traces 210 in scribe lines 208. Each die 204c includes pull-down resistor 232 electrically coupled to CADD #0 pad 206c.

FIG. 15 further illustrates a die contact circuit 222a (to the left) of probe card 222 (not shown) including test pins 240, power pins 242 and trace 244 electrically connecting power pins 242. In an embodiment, all die contact circuits 222a are identical, and each are customized for wafer 200 to touch-down on each pair of die 204c connected by electrical traces 210.

FIG. 15 shows a top view of the portion of wafer 200 and bottom view of die contact circuit 222a. As indicated by the arrow, probe card 222 (and die contact circuit 222a) would be flipped over when supported on PCB 220 so that, when die contact circuit 222a touches down on wafer 200 as shown in FIG. 16, test pins 240 touch-down on test pads 206a on one of the die 204c in each die pair.

In the embodiment shown, test pins 240 are positioned on each die contact circuit 222a to touch-down on the right side die 204c of each die pair. In further embodiments, test pins 240 may be positioned at the opposed side on each die contact circuit 222a to touch-down on the left side die 204c of each die pair.

With each die pair electrically coupled to each other by electrical traces 210, signals are transmitted to and from test heads of test head assembly 216 through PCB 220 and die contact circuits 222a to test each die pair simultaneously. Thus, as above, even where wafer 200 includes large numbers of die 204c, effectively halving the number of die 204c leaves more than enough test heads of test head assembly 216 to simultaneously test each of the die pairs in a single touch-down.

In accordance with the present technology, signals from like channels of a given die pair are distinguished from one another by pull-down resistor 232, power pins 242 and trace 244. The VCCQ power pad 206d may be connected to a power signal in test assembly 214.

As shown in FIG. 16, when die contact circuit 222a touches down on wafer 200, pull-down resistor 232 pulls the CADD #0 pad down to logical Address 0. However, for the left hand die 204c, when die contact circuit 222a touches down on wafer 200, power pins 242 touch-down on VCCQ power pad 206d and CADD #0, respectively. Trace 244 on die contact circuit 222a electrically connects VCCQ power pad 206d to CADD #0 pad.

During the electrical test, VCCQ power pad 206d is connected to power so that when coupled to VCCQ power pad 206d by trace 244 on touch-down, CADD #0 pad is pulled up to logical Address 1. This allows the channels on each die 204c in a die pair to be distinguished from each other, for example enabling the die 204c with Address 0 to be tested first, and enabling the die 204c with Address 1 to be tested second (or vice-versa). Given the unique address of each die 204c, the die 204c in a die pair may be tested simultaneously in further embodiments.

The relative positions of power pins 242 and trace 244 on die contact circuit 222a may be reversed in further embodiments to assign Address 0 to the left side die 204c in each die pair, and Address 1 to the right side die 204c of each die pair. Moreover, as noted, in further embodiments, the die 204c in each die pair may be vertically oriented with respect to each other.

The positions of test pins 240, power pins 242 and trace 244 on die contact circuits 222a may be adjusted accordingly where die pairs are vertically oriented to provide the appropriate contact of test pins 240 with test pads 206a of each die pair, and to provide the appropriate contact of power pins 242 on VCCQ power pad 206d and CADD pad 206c on each die 204c of each die pair. Although shown connected to pad CADD #0, the connection may be made to any CADD pad 206c.

Using any of the above-described embodiments, die 204 are electrically tested in step 108. The electrical testing may include test assembly 214 sending read/write instructions to the different memory locations on each die 204 and checking to ensure the instructions were properly implemented. The testing step 108 may be used to sort the die 204 into different bins, depending on how well the die 204 do in the testing step.

Referring again to the flowchart of FIG. 1, after die 204 are electrically tested in step 108, a layer of tape may be laminated onto first major surface 202 of wafer 200 in step 110. Wafer 200 may then be turned over, and diced in step 112. In embodiments, wafer 200 may be diced using stealth dicing before grinding (SDBG).

With the first major (active) surface of wafer 200 supported on a chuck, a laser (not shown) may emit a pulsed laser beam at a wavelength that transmits through the second major surface of wafer 200, for example at infrared or near-infrared wavelengths, to create a number of pinpoint holes at an intermediate depth of the wafer. The laser may be moved in rows and columns along scribe lines 208 in a plane of wafer 200 to define the outline of each die 204. The pinpoint holes generate cracks in wafer 200 along crystalline planes to effectively dice die 204 from semiconductor wafers 200.

Of relevance to the present technology, the dicing step 110 severs electrical traces 210 between the pairs of die 204 to electrically isolate each die 204 from one another. Instead of dicing by SDBG, die 204 may be diced from wafer 200 by sawing, water jet cutting or other methods. Each such method severs electrical traces 210 between the pairs of die 204.

After the dicing step 112, wafer 200 may then be thinned in step 114 using a grinding wheel (not shown) applied to the second major surface. The grinding wheel may thin wafer 200 from for example 780 μm to its final thickness. In embodiments, the final wafer thickness may be between 25 μm and 102 μm, such as for example between 25 μm and 36 μm. It is understood that wafer 200 may be thinner or thicker than this range after the backgrind step in further embodiments.

After completing backgrind step 114, a layer of die attach film (DAF) adhered to a flexible dicing tape may be applied to a second major surface of wafer 200 in step 116. Wafer 200 may then be turned over and supported on a chuck or other support surface, and the lamination tape on first major surface 202 of wafer 200 may be removed in step 118. Once on the chuck, the flexible dicing tape may be stretched along orthogonal axes to separate the individual die 204 in step 120 to allow the individual die 204 to be removed by a pick and place robot for inclusion in a semiconductor package.

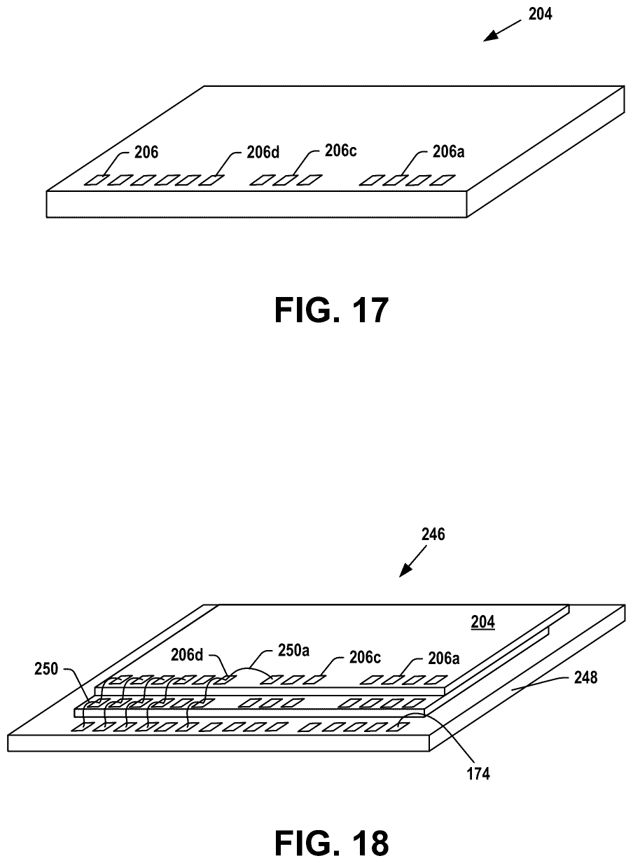

FIG. 17 shows a die 204 after separation from wafer 200. The illustration shows die bond pads 206, including test pads 206a, CADD address pads 206c and VCCQ power pad 206d. Again, the positions of these pads on the die 204 are shown by way of example only and may be otherwise arranged in further embodiments.

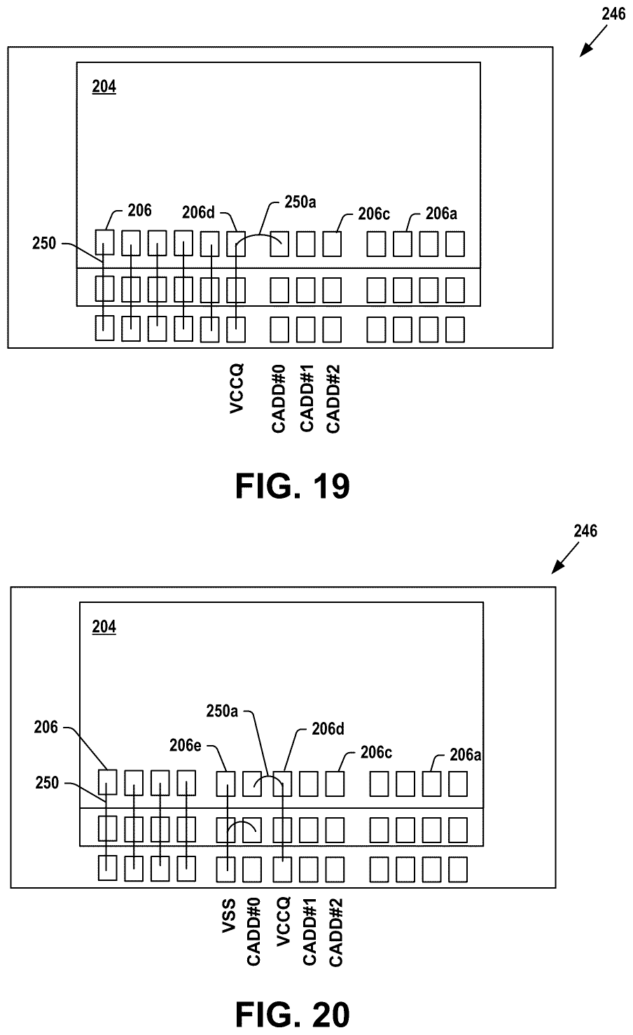

FIGS. 18 and 19 are perspective and top views of a semiconductor device 246 including a stack of die 204 formed according to the present technology. In step 122 (FIG. 1), the pick and place robot may stack die on a substrate 248. The stack is shown as including two die 204, but the stack may include more than two die 204 in further embodiments, including for example four, eight, sixteen, thirty-two or sixty-four semiconductor die. Die 204 are shown mounted on substrate 248, although die 204 may be formed in a chip scale package without a substrate in further embodiments.

It is typical to stack die 204 on a substrate, such as substrate 248, with an offset so that the bond pads of first (lower) die 204 are exposed when the next upper die 204 is added to the die stack. This allows the die bond pads of each die 204 to be electrically connected to one another and substrate 248 using bond wires (step 124, FIG. 1).

FIGS. 18 and 19 show bond wires 250 connecting same channel die bond pads 206 to each other and substrate 248 down the die stack. In FIGS. 18 and 19, no bond wires 250 are formed on test pads 206a, but the like-channel test pads 206a on different die 204 may be wire bonded together as in the other die bond pads 206 in further embodiments.

As like channels of each die 204 are electrically coupled to each other with bond wires 250, a methodology is needed to uniquely address each die 204 so that read/write instructions are performed on the desired die 204 in the die stack. In accordance with the present technology, each die 204 may be uniquely addressed using CADD pads 206c and VCCQ power pad 206d.

As seen in FIG. 18, an addressing bond wire 250a may be formed between VCCQ power pad 206d and pad CADD #0 of the top die 204, but not the bottom die 204. Upon receiving a power signal from the substrate on VCCQ power pad 206d, the connection to the pad CADD #0 on the top die 204 with bond wire 250a will assign a logical Address 1 to the top die 204. Having no connection at CADD pads 206c, the bottom die 204 will have a logical Address 0. Using this scheme, die 204 in the die stack may be distinguished from each other for read/write operations.

FIGS. 18 and 19 show the top die 204 having a bond wire 250a between VCCQ power pad 206d and CADD #0 pad. However, in further embodiments, the bottom die 204 (and not the top die 204) may have a bond wire 250a between VCCQ power pad 206d and CADD #0 pad. Moreover, bond wire 250a may couple VCCQ power pad 206d to any of CADD pads 206c in further embodiments.

It is understood that other voltage pads on die 204 may be coupled to one or more of CADD pads 206c to provide a voltage to the CADD pads and a unique address to each die 204 in semiconductor device 246. One such further embodiment is shown in the top view of FIG. 20.

Die 204 in FIG. 20 are configured with both pull-down resistor 232 and pull-up resistor 234 and trace 236 explained above with respect to FIGS. 8-12. In the embodiment of FIG. 20, one die 204 (e.g., the top die) may have trace 236 coupling the pull-down resistor 232 to a CADD pad 206c, and the other of the die 204 (the bottom die in this example) may have trace 236 coupling the pull-up resistor 234 to CADD pad 206c.

Using the die 204 with the CADD pad 206c coupled to pull-down resistor 232 and pull-up resistor 234, respectively, bond wires 250a may then be used to couple a CADD pad 206c (e.g., pad CADD #0) to the VSS power pad 206e on one of die 204. Bond wires 250a also may then be used to couple the selected CADD pad (pad CADD #0 in this example) to the VCCQ power pad 206d on the other of die 204. In this way, voltages to the VCCQ and VSS power pads 206d, 206e will assign unique addresses to the top and bottom die 204, with the top die 204 in FIG. 20 having logical Address 1 and the bottom die 204 in FIG. 20 having logical Address 0.

In embodiments described above, pad CADD #0 is shown connected to a power source to uniquely address the different die 204 packaged into semiconductor device 246. However, as noted, any of CADD pads 206c may be used. Moreover, more than one CADD pad 206c may be used to uniquely address each die 204 in semiconductor devices 246 having more than two die 204.

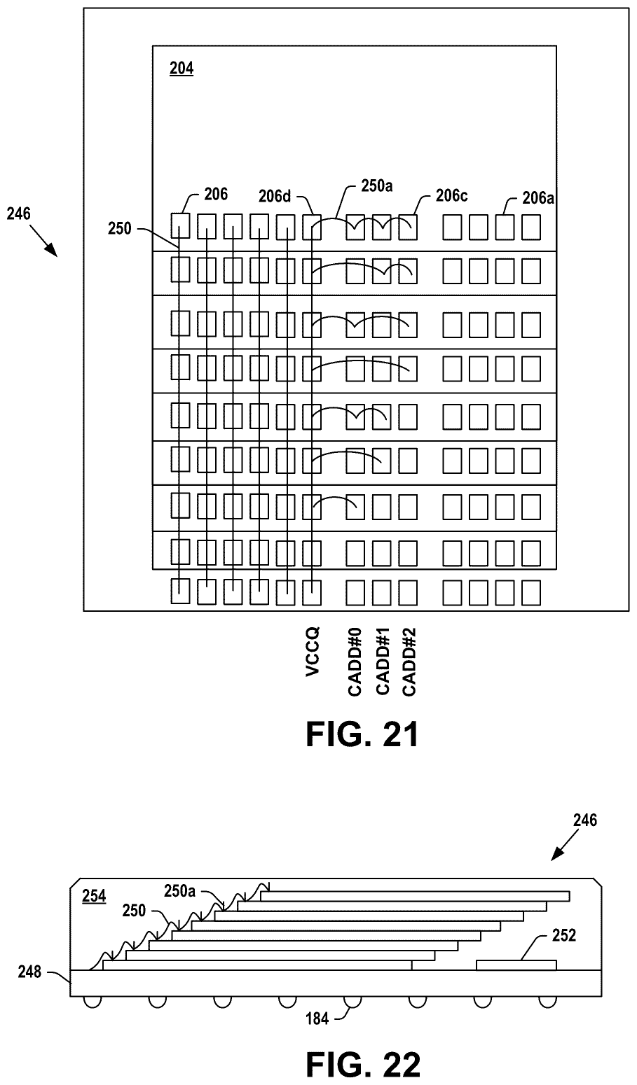

For example, FIG. 21 is a top view of a semiconductor device 246 including eight die 204. By providing unique connections between the three CADD pads CADD #0, CADD #1 and CADD #2 and a voltage pad VCCQ with bond wires 250a, each die 204 may be uniquely addressed. In the illustrated embodiment, die 204 have the connections and logical Addresses shown in the following Table 1:

TABLE 1

| | | Logic |
|---|---|---|
| Die | Connections between VCCQ and CADD pads | Address |
| 0 | None | 0 |
| 1 | Connection to CADD#0 | 1 |
| 2 | Connection to CADD#1 | 2 |
| 3 | Connection to CADD#1, CADD#0 | 3 |
| 4 | Connection to CADD#2 | 4 |
| 5 | Connection to CADD#2, CADD#0 | 5 |
| 6 | Connection to CADD#2, CADD#1 | 6 |
| 7 | Connection to CADD#2, CADD#1, CADD#0 | 7 |

Other schemes are contemplated for uniquely addressing large numbers of die 204 using bond wires 250a between voltage pads and different address pads on die 204.

FIG. 22 is an edge view of a completed semiconductor device 246 using die 204 tested and configured according to any of the above-described embodiments. Semiconductor device 246 is shown with a number of die 204 mounted on substrate 248, and bonded to each other and substrate 248 using bond wires 250 and addressing bond wires 250a.

Where die 204 are flash memory die, a controller die 252, such as an ASIC, may further be mounted on substrate 248 to control the exchange of data to and from die 204. In step 126 (FIG. 1), semiconductor device 246 may be encapsulated in a molding compound 254, which may for example be epoxy resin, Phenol resin, fused silica, crystalline silica, carbon black and/or metal hydroxide. Other molding compounds are contemplated.

In embodiments, semiconductor device 246 may be used as a BGA (ball grid array) package soldered to a host device such as a printed circuit board. In such embodiments, semiconductor device 246 may further include solder balls 184 on a bottom surface of substrate 248 for physically and electrically coupling semiconductor device 246 to the host device.

In embodiments described above, first and second die 204 in a given die pair may be distinguished from each other and uniquely addressed by a bond pad on the first die 204 being coupled to GROUND while a bond pad on the second die 204 is coupled to a voltage. However, it is understood that, instead of GROUND, the first and second die 204 in a given die pair may be distinguished from each other and uniquely addressed by a bond pad on the first die 204 being coupled to a first voltage while a bond pad on the second die 204 is coupled to a second voltage that is different than the first voltage.

In embodiments described above, traces 210 are used to electrically couple two die 204 to each other that are vertically adjacent or horizontally adjacent to each other. However, it is understood that traces 210 may be used to electrically couple two die 204 that are not adjacent to each other in further embodiments. The configuration of test pins, GROUND pins, power pins, etc., on die contact circuits 222a would be reconfigured accordingly to mate with non-adjacent die 204 paired by traces 210.

Thus, in the above described embodiments test pads 206a of pairs of die are coupled together by electrical traces 210 that extend between the die pairs in scribe lines 208, and die contact circuits 222a include test pins 228 that touch down on test pads 206a of one of the die 204 in each die pair. To distinguish between two common channels of a pair of coupled die, one die may have traces which electrically couple a chip address pad to a GROUND pin on the probe card while the other die has traces which electrically couple the chip address pad to a power pin on the probe card.

Although the above-described embodiments address the problem of the number of die on a wafer exceeding the number of test heads on the test equipment, there are some drawbacks to these techniques. First, traces 210 that extend between the die pairs in scribe lines 208 are typically formed in one of the metal layers used to fabricate the circuits of die 204. After die sort testing, traces 210 must be severed (e.g., in dicing step 110 of FIG. 1) to electrically isolate each die 204 from one another. But the process of severing traces 210 may introduce mechanical stress on die 204, and may cause metal peeling and electrical shorting of the metal layer used to form traces 210 with one or more other metal layers.

Second, near the periphery of die 204, but inside scribe lines 208, a die seal or edge seal structure may be used to protect die 204 from cracking while scribe lines 208 are cut (e.g., using a diamond cutter). A die seal or edge seal structure typically includes all existing layers stacked-metal layers and vias. Current generation die seal structures cannot be used with traces 210 extending between the die pairs in scribe lines 208, and new die seal technology would be required to do so.

One previously known solution uses two separate probe cards-a first probe card used in a first touch down to program a first set of die on a wafer to Address 0, and used in a second touch down to program a second set of die on a wafer to Address 1. And then a second probe card is used to touch down on the wafer and test all of the die on the wafer. Although this technique avoids the problems of traces 210 extending between the die pairs in scribe lines 208, the technique requires two separate probe cards and three touch downs on each wafer, which is very expensive and time consuming.

Technology is described to avoid these issues, but also address the problem of the number of die on a wafer exceeding the number of test heads on the test equipment. In embodiments, each die on a wafer has a chip address that may be selectively switched between a corresponding die sort chip address and an address that may be specified using one or more chip address bond pads. In embodiments, the die sort chip address of each die may be configured during manufacture using a metal or via option.

As described in more detail below, in embodiments during die sort testing, the chip address of multiple die on a wafer are selectively switched to their corresponding die sort chip address. In embodiments, a die sort test is performed in a single touch down of a probe card on the die on a wafer. In embodiments, the probe card includes test pins configured to touch down and couple together corresponding channels of the test pads to a single test head.

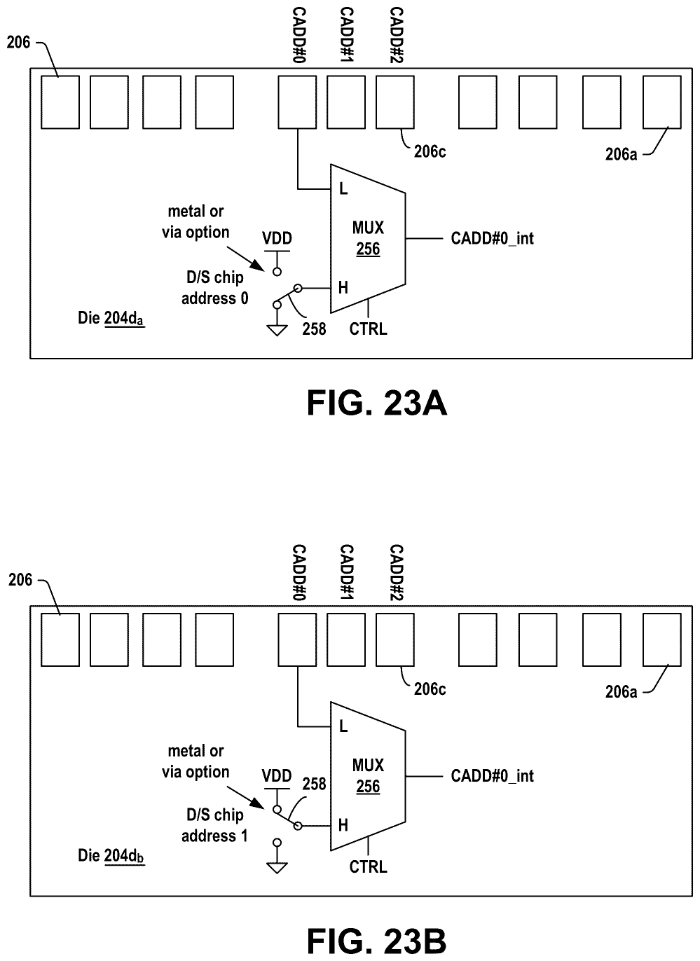

FIGS. 23A and 23B are top views of a pair of die 204d from wafer 200 according to another embodiment of this technology. Each die 204d includes die bond pads 206 including test pads 206a, and chip address pads CADD #0, CADD #1 and CADD #2 as described above.

In addition, each die 204d includes a multiplexor circuit (MUX) 256 having a first input terminal (e.g., L) coupled to one of chip address pads CADD #0, CADD #1 and CADD #2 (e.g., chip address pad CADD #0 in FIGS. 23A-23B), a second input terminal (e.g., H) coupled to a first end of a conductor 258, a third input terminal coupled to control signal CTRL, and an output terminal (e.g., CADD #0_int). In an embodiment, a signal value (e.g., a voltage) at CADD #0_int (referred to herein as “internal chip address CADD #0_int”) specifies the chip address (Address 0 or Address 1) of each die 204d.

In an embodiment, conductor 258 has a second end that may be coupled during fabrication of die 204d to either a first power supply (e.g., GROUND) or a second power supply (e.g., VDD). In an embodiment conductor 258 may be a metal option or a via option configured during fabrication of die 204d and is used to set a die-sort chip address (D/S chip address) of die 204d.

In an embodiment, the configuration of conductors 258 on die 204d are specified using two different layout data which have two different D/S chip addresses. That is, either of two different D/S chip addresses are assigned to die 204d on a reticle using first layout data and second layout data. In an embodiment, this may be implemented by taping out two kinds of layout data that have two different D/S chip addresses.

For example, FIG. 23A is a top view of a first die 204dₐ in a die pair, with a second end of conductor 258 coupled to GROUND (or 0) to specify a first D/S chip address (e.g., D/S chip address 0). FIG. 23B is a top view of a second die 204d_{b} in a die pair, with a second end of conductor 258 coupled to VDD (or 1) to specify a second D/S chip address (e.g., D/S chip address 1).

In an embodiment, MUX 256 selectively couples signals at first input terminal L and second input terminal H to output terminal CADD #0_int based on a value of control signal CTRL. For example, if control signal CTRL has a first value (e.g., LOW or 0) MUX 256 couples a signal at chip address pad CADD #0 to internal chip address CADD #0_int. Alternatively, if control signal CTRL has a second value (e.g., HIGH or 1) MUX 256 couples the D/S chip address value (e.g., 0 or 1) to internal chip address CADD #0 int.

For example, during die sort testing, control signal CTRL=1 and internal chip address CADD #0_int=D/S chip address. Thus, during die sort testing die 204dₐ in FIG. 23A has internal chip address CADD #0_int =D/S chip address 0 and die 204d_{b} in FIG. 23B has internal chip address CADD #0_int=D/S chip address 1. During normal operation (i.e., during a non-test mode), control signal CTRL=0, and internal chip address CADD #0_int=chip address CADD #0. Thus, chip address CADD #0 is used to set the chip address of each die 204d.

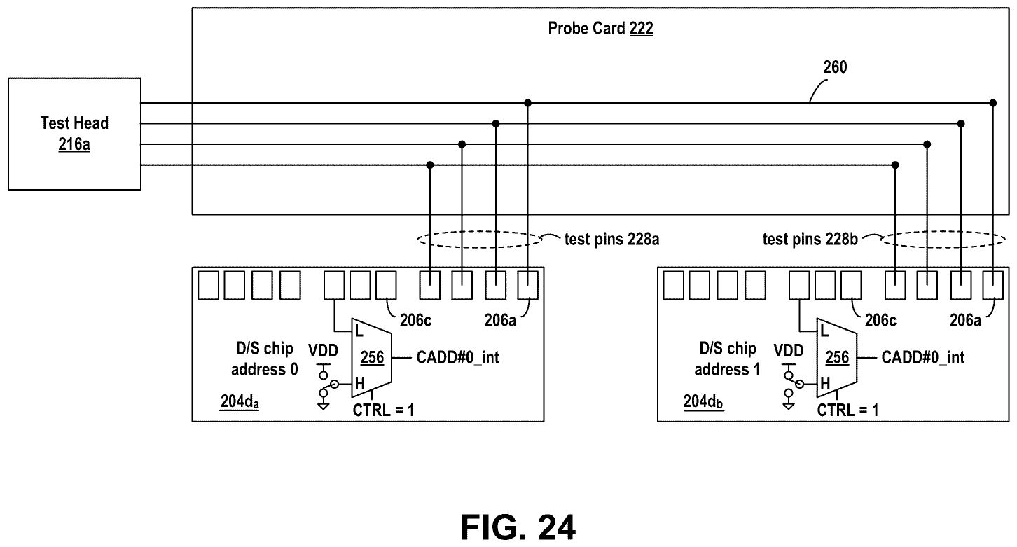

FIG. 24 depicts an embodiment of a die pair including die 204dₐ and die 204d_{b} of FIGS. 23A-23B with test pins 228a and 228b of probe card 222 touching down on test pads 206a of die 204dₐ and die 204d_{b}, respectively, during die sort testing. Test pins 228a and 228b are coupled to conductors 260, which couple together corresponding channels on each die 204dₐ and die 204d_{b} in the die pair to test head 216a.

Although die 204dₐ and die 204d_{b} are depicted disposed horizontally adjacent to one another, persons of ordinary skill in the art will understand that die 204dₐ and die 204d_{b} may be oriented in other ways relative to one another. For example, die 204dₐ and die 204d_{b} may be disposed vertically or diagonally adjacent to one another. Furthermore, in other embodiments die 204dₐ and die 204d_{b} need not be disposed immediately adjacent to one another. That is, one or more other die 204d may be horizontally and/or vertically disposed between die 204dₐ and die 204d_{b}.

During die sort testing, control signal CTRL=1, and thus die 204dₐ has internal chip address CADD #0_int=D/S chip address 0, and die 204d_{b} has internal chip address CADD #0_int=D/S chip address 1. This allows the channels on each die 204dₐ and die 204d_{b} in a die pair to be distinguished from each other.

For example, die 204dₐ with D/S chip address 0 may be tested first, and die 204d_{b} with D/S chip address 1 may be tested second (or vice-versa). In an embodiment, using the unique addresses provided by the D/S chip addresses, die 204dₐ and die 204d_{b} in each die pair may be tested simultaneously in further embodiments.

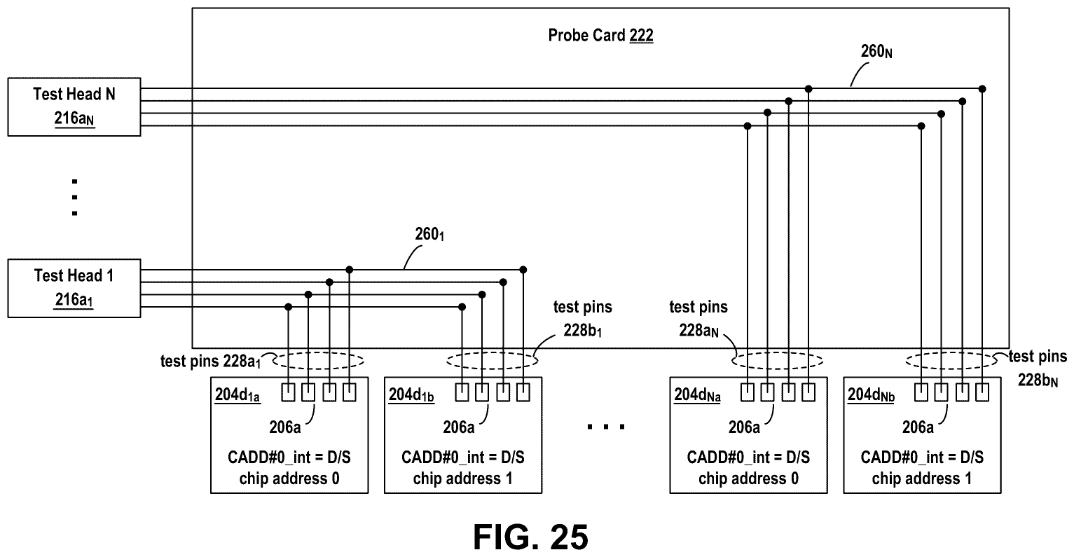

FIG. 25 is a diagram depicting multiple die pairs, each coupled to a corresponding test head 216a during die sort testing. To avoid overcrowding the drawing, MUXES 256, chip address pads CADD #0, CADD #1 and CADD #2 and control signal CTRL are omitted, and instead the CADD #0_int address is specified for each die 204d.

In an embodiment, FIG. 25 depicts test pins 228a₁ and 228b₁ of probe card 222 touching down on test pads 206a of die 204d₁ₐ and die 204d_{1b}, respectively, . . . , and test pins 228a_{N} and 228b_{N} of probe card 222 touching down on test pads 206a of die 204d_{Na} and die 204d_{Nb}, respectively, during die sort testing. Test pins 228a₁ and 228b₁ are coupled to conductors 260_{N}, which couple together corresponding channels on each die 204d_{Na} and die 204d_{Nb} in the die pair to test head 216a₁, . . . , test pins 228a_{N} and 228b_{N} are coupled to conductors 260_{N}, which couple together corresponding channels on each die 204d_{Na} and die 204d_{Nb} in the die pair to test head 216a_{N}, and so on. Thus, in this embodiment 2N die 204d₁ₐ, die 204d_{1b}, 204d₂ₐ, 204d_{2b}, . . . , 204d_{Na}, 204d_{Nb} may be tested during die sort testing using N test heads 216a₁, 216a₂, . . . , 216a_{N}.

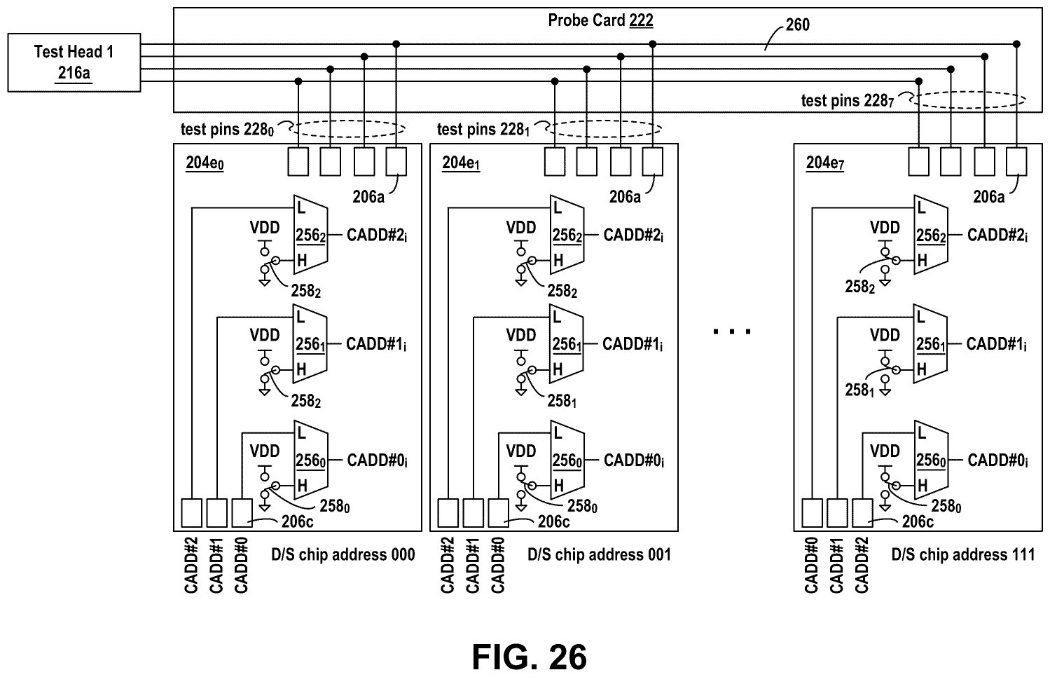

In the embodiments described above, a pair of die 204d are coupled to each test head 216a. In other embodiments, more than two die 204d may be coupled to each test head 216a. For example, FIG. 26 is a diagram depicting eight die 204e₀, 204e₁, . . . , 204e₇ from wafer 200 coupled to test head 216a, each die 204e having die bond pads 206 including test pads 206a, and chip address pads CADD #0, CADD #1 and CADD #2 as described above.

In addition, each die 204e includes MUXES 256₀, 256₁, 256₂, each having a first input terminal (e.g., L) coupled to a corresponding one of chip address pads CADD #0, CADD #1 and CADD #2, respectively, a second input terminal (e.g., H) coupled to a corresponding conductor 258₀, 258₁, 258₂, respectively,, a third input terminal coupled to control signal CTRL (not shown to avoid overcrowding the drawing), and an output terminal CADD #0_int, CADD #1_int, CADD #2_int, respectively. In an embodiment, internal chip addresses CADD #0_int, CADD #1_int, CADD #2_int specify the chip address (Address 000, Address 001, Address 010, . . . , Address 111) of each die 204e.

In an embodiment, each of conductors 258₀, 258₁, 258₂ has a first end coupled to second input terminal H of MUXES 256₀, 256₁, 256₂, respectively, and a second end that may be coupled to either a first power supply (e.g., GROUND) or a second power supply (e.g., VDD). In an embodiment conductors 258₀, 258₁, 258₂ may be a metal option or a via option configured during fabrication of die 204e and are used to set a D/S chip address of die 204e.

In an embodiment, the configuration of conductors 258₀, 258₁, 258₂ on die 204e are specified using eight different layout data which have eight different D/S chip addresses. That is, the different D/S chip addresses are assigned to die 204e on a reticle using first through eighth layout data. In an embodiment, this may be implemented by taping out eight kinds of layout data that have eight different D/S chip addresses.

As depicted in FIG. 26, probe card 222 includes test pins 228₀, 228₁, . . . , 228₇ touching down on test pads 206a of die 204e₀, 204e₁, . . . , 204e₇, respectively, during die sort testing. Test pins 228₀, 228₁, . . . , 228₇ are coupled to conductors 260, which couple together corresponding channels on each die 204e₀, 204e₁, . . . , 204e₇ to test head 216a.

During die sort testing, control signal CTRL=1, and thus die 204e₀ has internal chip address (CADD #0_int, CADD #1_int, CADD #2_int)=D/S chip address 000, die 204e₁ has internal chip address (CADD #0_int, CADD #1_int, CADD #2_int)=D/S chip address 001, . . . , die 204e₇ has internal chip address (CADD #0_int, CADD #1_int, CADD #2_int)=D/S chip address 111. This allows the channels on each die 204e₀, 204e₁, . . . , 204e₇ to be distinguished from one other.

For example, die 204e₀ may be tested first, die 204e₁ may be tested second, and so on. In an embodiment, using the unique addresses provided by the D/S chip addresses, die 204e₀, 204e₁, . . . , 204e₇ in each die octet may be tested simultaneously in further embodiments. Persons of ordinary skill in the art will understand that the technology described above may be used to couple test pins of more than or fewer than eight die 204 to a single test head 216a.

In an embodiment, during normal operation (i.e., during a non-test mode), control signal CTRL=0, and on each of die 204e₀, 204e₁, . . . , 204e₇ internal chip address CADD #0_int=chip address CADD #0, internal chip address CADD #1_int=chip address CADD #1, and internal chip address CADD #2_int=chip address CADD #2. Thus, chip addresses CADD #0, CADD #1, and CADD #2 are used to set the chip address of each of die 204e₀, 204e₁, . . . , 204e₇.

Although die 204e₀, 204e₁, . . . , 204e₇ are depicted disposed horizontally adjacent to one another, persons of ordinary skill in the art will understand that die 204e₀, 204e₁, . . . , 204e₇ may be oriented in other ways relative to one another. For example, die 204e₀, 204e₁, . . . , 204e₇ may be disposed vertically or diagonally adjacent to one another. Furthermore, in other embodiments die 204e₀, 204e₁, . . . , 204e₇ need not be disposed immediately adjacent to one another. That is, one or more other die 204e may be horizontally and/or vertically disposed between various die 204e₀, 204e₁, . . . , 204e₇.

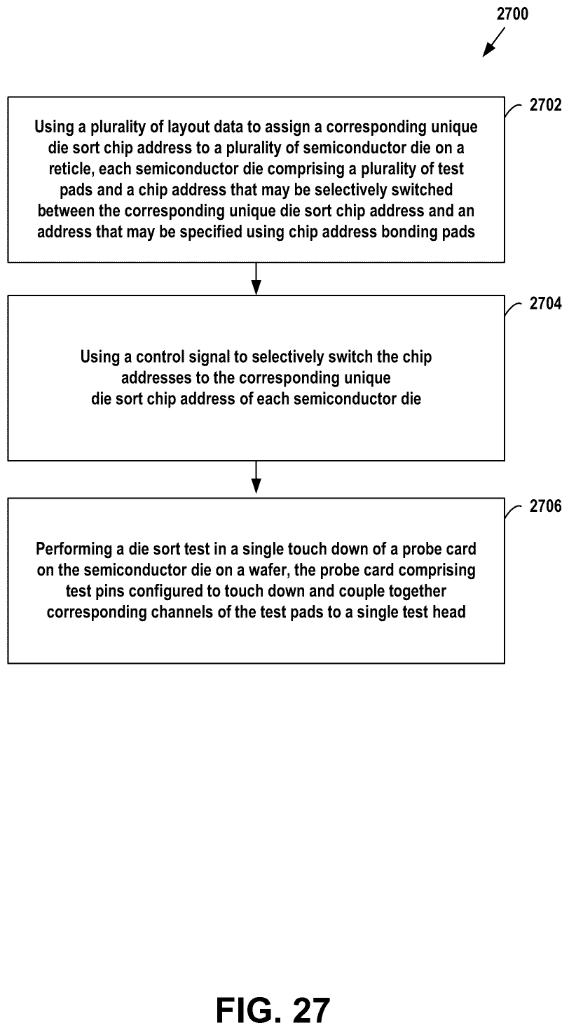

FIG. 27 is a flow diagram of a process 2700 for performing a single touch-down die sort testing of multiple semiconductor die on a wafer. In an embodiment, process 2700 may be performed during manufacture and testing of the semiconductor die on the wafer.

At step 2702, using a plurality of layout data to assign a corresponding unique die sort chip address to a plurality of semiconductor die on a reticle, each semiconductor die including a plurality of test pads and a chip address that may be selectively switched between the corresponding unique die sort chip address and an address that may be specified using chip address bonding pads.

At step 2704, using a control signal to selectively switch the chip addresses to the corresponding unique die sort chip address of each semiconductor die.

At step 2706, performing a die sort test in a single touch down of a probe card on the semiconductor die on a wafer, the probe card including test pins configured to touch down and couple together corresponding channels of the test pads to a single test head.

In an embodiment, an apparatus is provided that includes a semiconductor wafer including a first die and a second die, each including, a selector circuit including a first input terminal coupled to a first die bond pad, a second input terminal, and an output terminal, the selector circuit configured to selectively couple the first input terminal and the second input terminal to the output terminal, a conductor selectively configured to couple the second input terminal to either a first power supply or a second power supply, and an address determined based on a signal value at the output terminal of the selector circuit.

In an embodiment, an apparatus is provided that includes a plurality of semiconductor die, each including a multiplexor circuit including a first input terminal, a second input terminal, a third input terminal coupled to a control signal, and an output terminal selectively coupled to the first input terminal and the second input terminal based on a value of the control signal, a conductor configured during fabrication of the semiconductor die to couple the second input terminal of the multiplexor circuit to either of a first signal value and a second signal value, and a semiconductor die address that is determined based on a signal value at the output terminal of the multiplexor circuit.

In an embodiment, a method is provided that includes using a plurality of layout data to assign a corresponding unique die sort chip address to a plurality of semiconductor die on a reticle, each semiconductor die including a plurality of test pads and a chip address that may be selectively switched between the corresponding unique die sort chip address and an address that may be specified using chip address bonding pads, using a control signal to selectively switch the chip addresses to the corresponding unique die sort chip address of each semiconductor die, and performing a die sort test in a single touch down of a probe card on the semiconductor die on a wafer, the probe card including test pins configured to touch down and couple together corresponding channels of the test pads to a single test head.

The foregoing detailed description of the disclosed technology has been presented for purposes of illustration and description. It is not intended to be exhaustive or to limit the disclosed technology to the precise form disclosed. Many modifications and variations are possible in light of the above teaching. The described embodiments were chosen to best explain the principles of the disclosed technology and its practical application to thereby enable others skilled in the art to best utilize the disclosed technology in various embodiments and with various modifications as are suited to the particular use contemplated. It is intended that the scope of the disclosed technology be defined by the claims appended hereto.

1. An apparatus comprising:
a semiconductor wafer comprising a first die and a second die, each comprising:
a selector circuit comprising a first input terminal coupled to a first die bond pad, a second input terminal, and an output terminal, the selector circuit configured to selectively couple the first input terminal and the second input terminal to the output terminal;
a conductor selectively configured to couple the second input terminal to either a first power supply or a second power supply; and
an address determined based on a signal value at the output terminal of the selector circuit.

2. The apparatus of claim 1, wherein the conductor of each of the first die and the second die is selectively configured during fabrication of the first die and the second die.

3. The apparatus of claim 1, wherein the conductor of each of the first die and the second die is selectively configured using any of a metal option and a via option.

4. The apparatus of claim 1, wherein the conductor of each of the first die and the second die is selectively configured using first layout data and second layout data.

5. The apparatus of claim 1, wherein the conductor of each of the first die and the second die is selectively configured to assign a unique address to each of the first die and the second die.

6. The apparatus of claim 1, wherein the selector circuit of each of the first die and the second die is configured to selectively couple the second input terminal to the output terminal during a test mode.

7. The apparatus of claim 6, wherein the test mode comprises a die sort test.

8. The apparatus of claim 1, wherein the selector circuit of each of the first die and the second die is configured to selectively couple the first input terminal to the output terminal during a non-test mode.

9. The apparatus of claim 1, wherein:
each of the first die and the second die comprises a second die bond pad that comprises a test pad; and
the test pads of the first die and the second die are configured to be coupled to a same test head during a test mode.

10. The apparatus of claim 1, wherein:
each of the first die and the second die comprises a second die bond pad that comprises a test pad;
a first pin of a probe card is configured to touch down on the test pad of the first die and a second pin of the probe card is configured to touch down on the test pad of the second die; and
the first pin and the second pin are coupled together and are coupled to a test head during a test mode.

11. The apparatus of claim 1, wherein the first bond pad of each of the first die and the second die comprises a chip address pad.

12. The apparatus of claim 1, wherein signal values at the first bond pad of each of the first die and the second die are used to set an address of each of the first die and the second die during a non-test mode.

13. The apparatus of claim 1, wherein the first die and the second die may be any of:
horizontally adjacent die on the semiconductor wafer;
vertically adjacent die on the semiconductor wafer; and
diagonally adjacent die on the semiconductor wafer.

14. The apparatus of claim 1, wherein the first die and the second die are not disposed immediately adjacent to one another.

15. An apparatus comprising:
a plurality of semiconductor die, each comprising:
a multiplexor circuit comprising a first input terminal, a second input terminal, a third input terminal coupled to a control signal, and an output terminal selectively coupled to the first input terminal and the second input terminal based on a value of the control signal;
a conductor configured during fabrication of the semiconductor die to couple the second input terminal of the multiplexor circuit to either of a first signal value and a second signal value; and
a semiconductor die address that is determined based on a signal value at the output terminal of the multiplexor circuit.

16. The apparatus of claim 15, wherein the control signal comprises a first value during a test mode, and a second value during a non-test mode.

17. The apparatus of claim 16, wherein the test mode comprises a die sort test.

18. The apparatus of claim 15, wherein:
the plurality of semiconductor die each comprise a test bond pad; and
a probe card is configured to touch down on the test bond pads of each of the plurality of semiconductor die and couple the test bond pads to a single test head for simultaneously testing the plurality of semiconductor die.

19. The apparatus of claim 15, wherein each of the plurality of semiconductor die comprises a chip address bond pad coupled to the first input terminal of the multiplexor circuit.

20. A method comprising:
using a plurality of layout data to assign a corresponding unique die sort chip address to a plurality of semiconductor die on a reticle, each semiconductor die comprising a plurality of test pads and a chip address that may be selectively switched between the corresponding unique die sort chip address and an address that may be specified using chip address bonding pads;
using a control signal to selectively switch the chip addresses to the corresponding unique die sort chip address of each semiconductor die; and
performing a die sort test in a single touch down of a probe card on the semiconductor die on a wafer, the probe card comprising test pins configured to touch down and couple together corresponding channels of the test pads to a single test head.
